(19) United States
(12) Patent Application Publication
(10) Pub. No.: US 2007/0114612 A1
(43) Pub. Date: May 24, 2007

(54) Method of fabricating semiconductor devices having MCFET/finFET and related device

(75) Inventors: Young-Joon Ahn, Yongin-si (KR); Choong-Ho Lee, Seongnam-si (KR); Hee-Soo Kang, Anyang-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/443,816

(22) Filed: May 31, 2006

(30) Foreign Application Priority Data
Nov. 24, 2005 (KR) 10-2005-0113133

(51) Int. Cl. H01L 29/78; H01L 21/336

(52) U.S. Cl. 257/364; 438/585; 438/283

(57) ABSTRACT

In a method of fabricating a semiconductor device having both a MCFET and a finFET on a common substrate, a first hard mask pattern and a second hard mask pattern are formed on a substrate, the second hard mask pattern having a width in a horizontal direction that is less than that of the first hard mask pattern, and the second hard mask pattern being spaced apart from the first hard mask pattern. The substrate is partially removed using the first and second hard mask patterns as etch masks, and forming a preliminary multi-fin structure below the first hard mask pattern and a single fin structure below the second hard mask pattern. A concave portion is formed in the preliminary multi-fin structure to form a multi-fin structure.

### CROSS-REFERENCE TO RELATED APPLICATION

This application claims priority to Korean Patent Application No. 2005-0113133, filed Nov. 24, 2005, the contents of which are hereby incorporated herein by reference in their entirety.

### BACKGROUND OF THE INVENTION

1. Field of the Invention

The present invention relates to a semiconductor device and a method of fabricating the same, and more particularly, to a method of fabricating a semiconductor device having a Multi-channel Field Effect Transistor (MCFET) and a finFET on a common substrate, and a related device.

2. Description of the Related Art

As semiconductor devices continue to become more highly integrated, reduction in the size of a field effect transistor (FET) has been continuously researched. In the case of the conventional semiconductor device having a planar transistor, the reduction in size of the transistor necessarily corresponds to a reduction in the channel length and width of the transistor. As the channel length is reduced, device performance such as operating speed of the semiconductor device, as well as integration density, are enhanced. However, such a reduction in channel length can cause many problems such as the short channel effect. Also, a reduction in channel width decreases the current driving capability of a transistor.

To improve such problems, a finFET has been proposed. The finFET has a silicon fin that protrudes from a substrate, and an insulated gate electrode covering both sidewalls and a top surface of the silicon fin. Source and drain regions are disposed in the silicon fin at both sides of the gate electrode. Accordingly, a channel region of the finFET is formed on surfaces of the top surface and both sidewalls of the fin. That is, the effective channel width of the finFET is relatively increased, as compared to a planar transistor having the same planar area. In addition, a gate electrode is disposed to cover both sides of the channel region, so that the control parameters of the gate electrode for the channel region may be enhanced. In particular, when the distance between the sidewalls is not more than twice the channel depletion depth, the silicon fin can be fully depleted, so as to have excellent electrical characteristics.

However, a semiconductor device may require FETs having different on-current characteristics with respect to each other to be formed on a single, common. substrate. For example, a memory device such as a dynamic random access memory (DRAM) includes cell transistors and peripheral circuit transistors. A peripheral circuit transistor may require an on-current that is larger than that of the cell transistor. There is disclosed a method for implementing FETs having different on-currents with respect to each other by making the heights of the silicon fin different from each other. However, making the heights of the silicon fin different causes the fabrication process to be relatively complicated. In an alternative approach, there is disclosed a method for increasing the size of the top surface of the silicon fin. In this case, as the thickness of the silicon fin increases, the characteristics of the finFET are adversely affected. In addition, the method for increasing the top surface of the silicon fin reduces the integration density of the resulting device.

Example processes for forming FET devices having different on currents with respect to each other, and example FET devices having such properties are disclosed in U.S. Pat. No. 6,911,383 B2 entitled “HYBRID PLANAR AND FINFET CMOS DEVICES” to Doris et al. In Doris et al., a semiconductor device having a planar FET and a finFET is provided on the same silicon on insulator (SOI) substrate.

Alternatively, a method for increasing an effective channel width of the FET is disclosed in U.S. Pat. No. 6,872,647 B1 entitled “METHOD FOR FORMING MULTIPLE FINS IN A SEMICONDUCTOR DEVICE” to Yu et al. According to Yu et al., a structure having a top surface and side surfaces is formed on a semiconductor substrate such as an SOI substrate. Spacers are formed on the side surfaces of the structure. The semiconductor substrate is selectively removed using the spacers as etch masks to form fins.

Nevertheless, an improved technique of forming FETs having different on-currents with respect to each other on a common substrate is desired, in an effort to further reduce fabrication complexity so as to minimize fabrication costs, and to further increase integration density.

### SUMMARY OF THE INVENTION

An embodiment of the invention provides a method of simultaneously forming FETs having different on-currents with respect to each other on a single, common, substrate.

Another embodiment of the invention provides a semiconductor device having a multi-channel field effect transistor (MCFET) and a finFET on a single, common, substrate.

In one aspect, the present invention is directed to a method of fabricating a semiconductor device, comprising: forming a first hard mask pattern and a second hard mask pattern on a substrate, the second hard mask pattern having a width in a horizontal direction that is less than that of the first hard mask pattern, and the second hard mask pattern being spaced apart from the first hard mask pattern; partially removing the substrate using the first and second hard mask patterns as etch masks, and forming a preliminary multi-fin structure below the first hard mask pattern and a single fin structure below the second hard mask pattern; and forming a concave portion in the preliminary multi-fin structure to form a multi-fin structure.

In one embodiment, the first and second hard mask patterns are formed of a nitride layer.

In another embodiment, the concave portion is positioned in a central region of the multi-fin structure in the horizontal direction.

In another embodiment, forming the concave portion comprises: forming a multi-channel mask on the substrate, the multi-channel mask having a first opening partially exposing a top surface of the preliminary multi-fin structure; and anisotropically etching the preliminary multi-fin structure using the multi-channel mask as an etch mask.

In another embodiment, forming the multi-channel mask comprises: etching the first and second hard mask patterns using a pull-back process to form a first hard mask reduced pattern on the preliminary multi-fin structure; forming a sacrificial layer covering the substrate and exposing a top surface of the first hard mask reduced pattern; patterning the sacrificial layer and the first hard mask reduced pattern to form a sacrificial line that crosses over the preliminary multi-fin structure and the single fin structure in the horizontal direction, the sacrificial line having a sacrificial pattern and a first sacrificial mask; forming a passivation layer on the substrate at both sides of the sacrificial line; and selectively removing the first sacrificial mask.

In another embodiment, the pull-back process is performed until the second hard mask pattern is completely removed.

In another embodiment, forming the multi-channel mask comprises: partially removing the first and second hard mask patterns using a pull-back process to form a first hard mask reduced pattern and a second hard mask reduced pattern; forming a sacrificial layer covering the substrate and exposing top surfaces of the first and second hard mask reduced patterns; patterning the sacrificial layer and the first and second hard mask reduced patterns to form a sacrificial line that crosses over the preliminary multi-fin structure and the single fin structure, the sacrificial line having a sacrificial pattern, a first sacrificial mask, and a second sacrificial mask; forming a passivation layer on the substrate at both sides of the sacrificial line; selectively removing the first and second sacrificial masks to form the first opening and a second opening; and forming a spacer on inner sidewalls of the first opening, and forming a sacrificial plug in the second opening.

In another embodiment, the pull-back process comprises isotropically etching the first and second hard mask patterns.

In another embodiment, the sacrificial layer and the passivation layer are formed of a material layer having an etch selectivity with respect to the hard mask patterns.

In another embodiment, forming the spacer and the sacrificial plug comprises: forming a spacer layer filling the second opening and covering an inner wall of the first opening; and anisotropically etching the spacer layer until the top surface of the preliminary multi-fin structure is exposed on a bottom surface of the first opening.

In another embodiment, the multi-fin structure and the single fin structure have substantially the same height.

In another aspect, the present invention is directed to a method of fabricating a static random access memory (SRAM) cell, comprising: forming a preliminary multi-fin structure and a single fin structure on a substrate that extend from the substrate in a vertical direction, the preliminary multi-fin structure having a width in a horizontal direction that is greater than that of the single fin structure; forming a concave portion in the preliminary multi-fin structure to form a multi-fin structure; forming a gate dielectric layer on the multi-fin structure and the single fin structure; and forming a first electrode crossing the multi-fin structure and a second gate electrode crossing the single fin structure.

In one embodiment, forming the preliminary multi-fin structure and a single fin structure comprises: forming a first hard mask pattern and a second hard mask pattern on the substrate, the second hard mask pattern having a width in the horizontal direction that is less than that of the first hard mask pattern, the first and second hard mask patterns being spaced apart from each other; and partially removing the substrate using the hard mask patterns as etch masks, wherein the preliminary multi-fin structure is formed under the first hard mask pattern and the single fin structure is formed under the second hard mask pattern.

In another embodiment, the first and second hard mask patterns are formed of a nitride layer.

In another embodiment, forming the concave portion comprises: forming a multi-channel mask on the substrate, the multi-channel mask having a first opening partially exposing a top surface of the preliminary multi-fin structure; and anisotropically etching the preliminary multi-fin structure using the multi-channel mask as an etch mask.

In another embodiment, forming the multi-channel mask comprises: partially removing the first and second hard mask patterns using a pull-back process to form a first hard mask reduced pattern and a second hard mask reduced pattern; forming a sacrificial layer covering the substrate and exposing top surfaces of the first and second hard mask reduced patterns; patterning the sacrificial layer and the hard mask reduced patterns to form a sacrificial line that crosses over the preliminary multi-fin structure and the single fin structure, the sacrificial line having a sacrificial pattern, a first sacrificial mask, and a second sacrificial mask; forming a passivation layer on the substrate at both sides of the sacrificial line; selectively removing the first and second sacrificial masks to form the first opening and a second opening; and forming a spacer on inner sidewalls of the first opening, and forming a sacrificial plug in the second opening.

In another embodiment, the sacrificial layer and the passivation layer are formed of a material layer having an etch selectivity with respect to the first and second hard mask patterns.

In another embodiment, the first gate electrode fills the concave portion and covers at least one sidewall of the multi-fin structure, and the second gate electrode covers at least one sidewall of the single fin structure.

In another aspect, the present invention is directed to a semiconductor device comprising: a substrate; a multi-fin structure that extends from the substrate in a vertical direction, the multi-fin structure including a concave portion in a top portion thereof; a single fin structure that protrudes from the substrate in the vertical direction, the single-fin structure spaced apart from the multi-fin structure and having a width that is less than that of the multi-fin structure; a first gate electrode crossing the multi-fin structure; a second gate electrode crossing the single fin structure and covering at least one sidewall of the single fin structure; and a gate dielectric layer interposed between the multi-fin structure and the single fin structure and between the first and second gate electrodes.

In one embodiment, the concave portion is positioned in a central region of the multi-fin structure in the horizontal direction, and the first gate electrode fills the concave portion and covers at least one sidewall of the multi-fin structure.

In another embodiment, the multi-fin structure and the single fin structure have substantially the same height.

In another embodiment, the second gate electrode covers both sidewalls of the single fin structure.

In another aspect, the present invention is directed to a semiconductor device having a MCFET and a finFET on a common substrate. The semiconductor device includes a substrate, and a multi-fin structure that protrudes from the substrate and having a concave portion in the multi-fin structure. In addition, a single fin structure is provided, which protrudes from the substrate and has a width that is less than that of the multi-fin structure. A first gate electrode is disposed across the multi-fin. A second gate electrode is disposed across the single fin and covers at least one sidewall of the single fin. A gate dielectric layer is interposed between the fins and the gate electrodes.

### BRIEF DESCRIPTION OF THE DRAWINGS

The foregoing and other objects, features and advantages of the invention will be apparent from the more particular description of a preferred embodiment of the invention, as illustrated in the accompanying drawing. The drawing is not necessarily to scale, emphasis instead being placed upon illustrating the principles of the invention.

FIGS. 1 to 7, 9, and 11 are perspective views illustrating a method of fabricating a semiconductor device having a MCFET and a finFET in accordance with an embodiment of the present invention.

FIG. 8 is a cross-sectional view taken along section line I-I′ of FIG. 7.

FIG. 10 is a cross-sectional view taken along section line I-I′ of FIG. 9.

FIG. 12 is a cross-sectional view taken along section line I-I′ of FIG. 11.

FIG. 13 is an equivalent circuit diagram of a complementary metal oxide semiconductor (CMOS) static random access memory (SRAM) cell including both a MCFET and a finFET in accordance with an embodiment of the present invention.

### DETAILED DESCRIPTION OF EMBODIMENTS OF THE INVENTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete. In the drawings, the thickness of layers and regions are exaggerated for clarity. In addition, when a layer is described to be formed on another layer or on a substrate, this means that the layer may be formed on the other layer or on the substrate, or a third layer may be interposed between the layer and the other layer or the substrate. Like numbers refer to like elements throughout the specification.

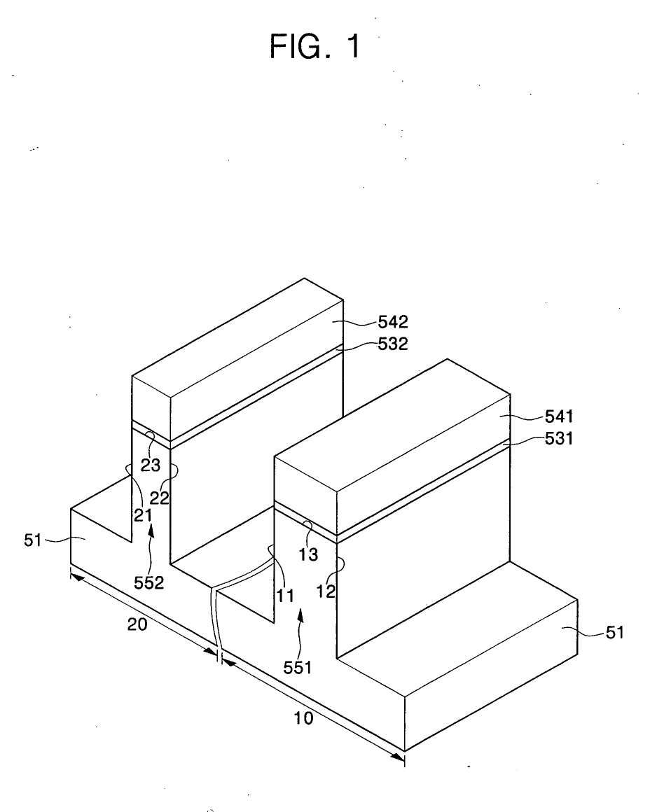

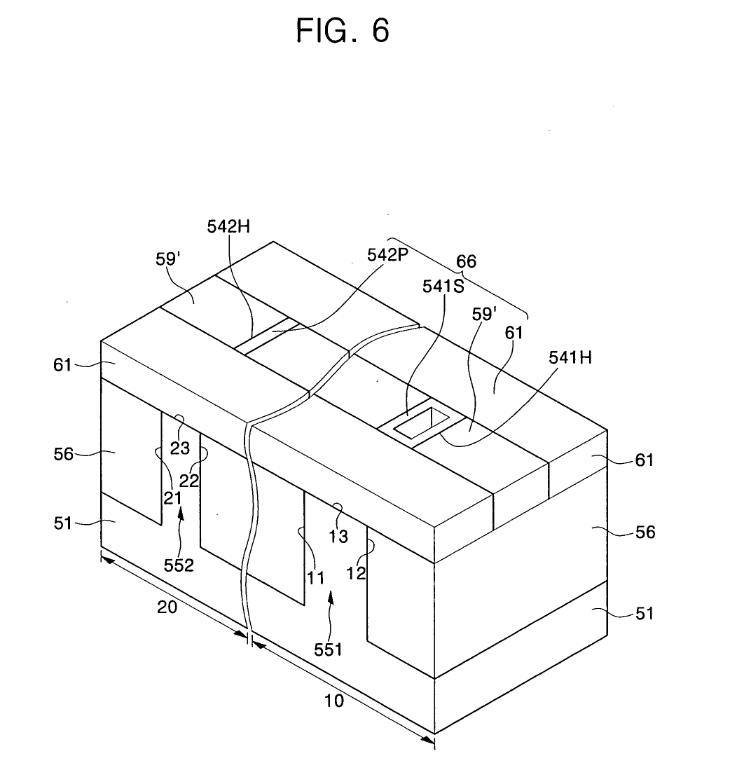

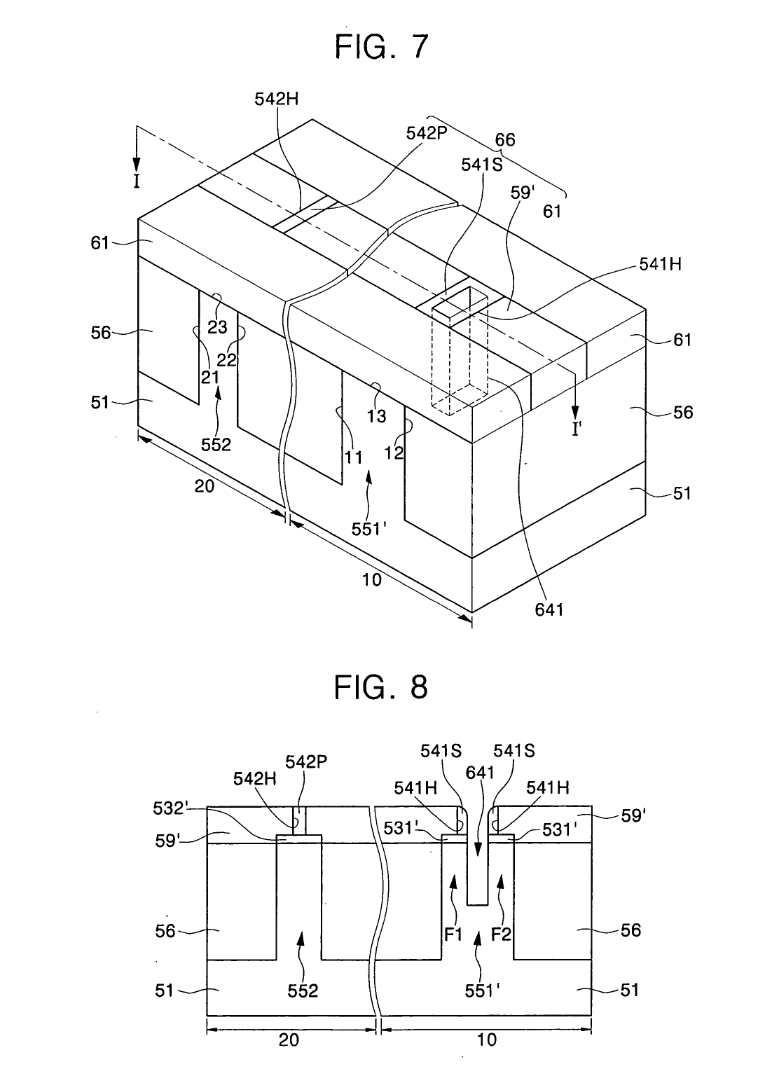

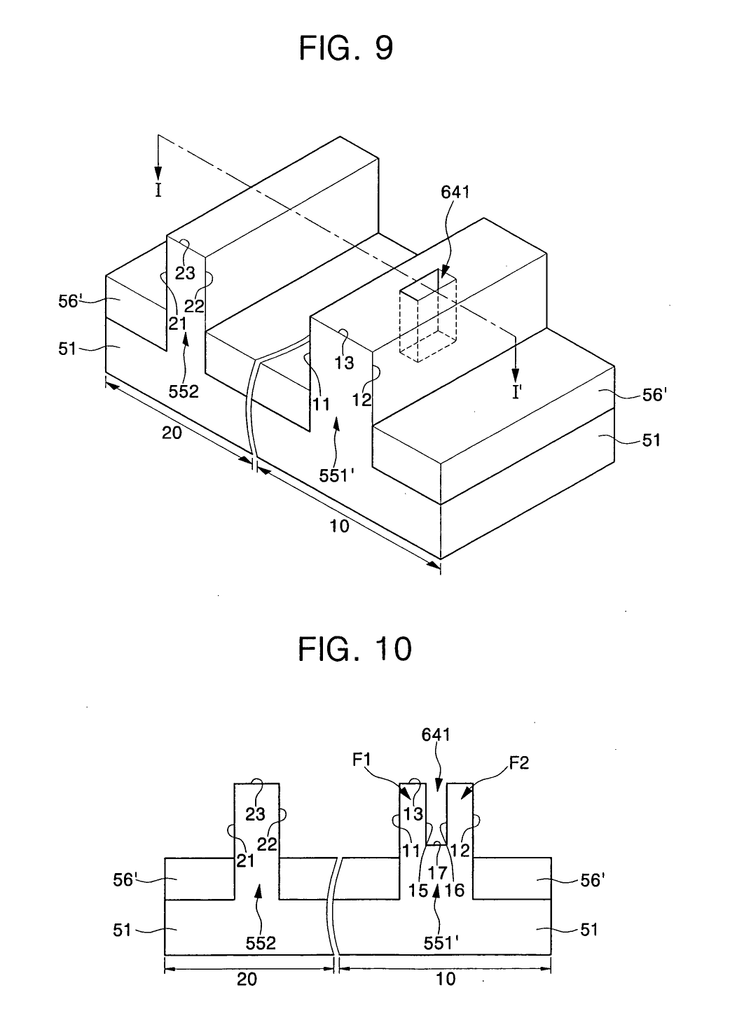

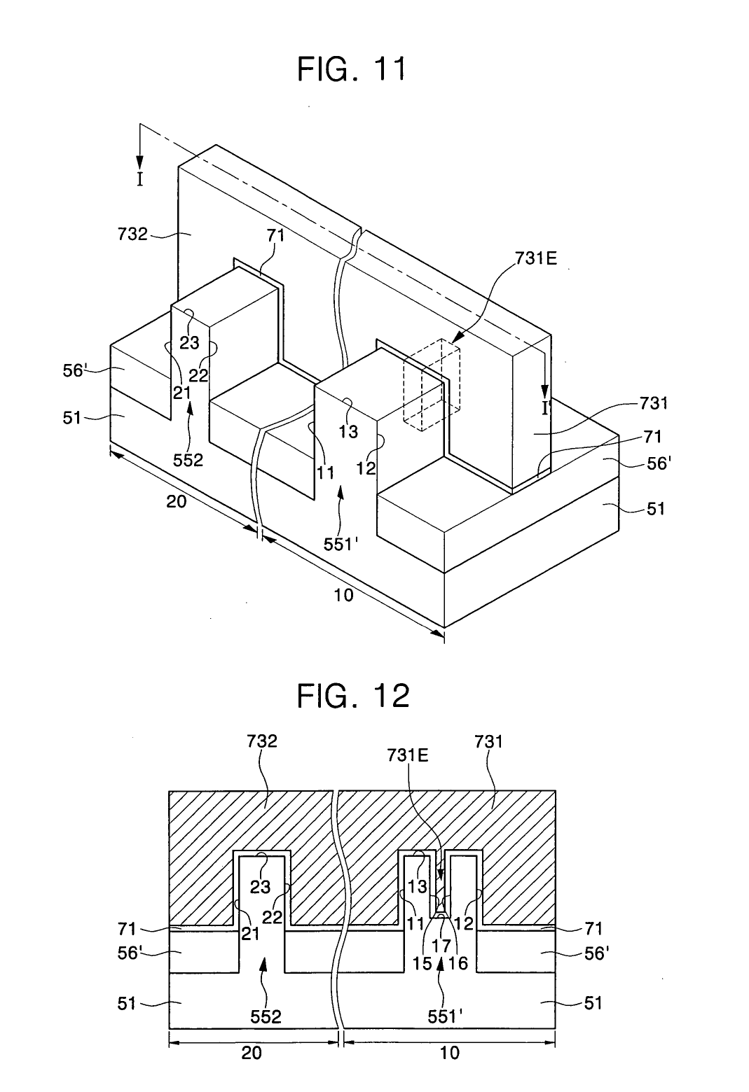

FIGS. 1 to 7, 9, and 11 are perspective views illustrating a method of fabricating a semiconductor device having a MCFET and a finFET in accordance with an embodiment of the present invention. FIG. 8 is a cross-sectional view taken along section line I-I′ of FIG. 7, FIG. 10 is a cross-sectional view taken along section line I-I′ of FIG. 9, and FIG. 12 is a cross-sectional view taken along section line I-I′ of FIG. 11.

First, a method of fabricating a semiconductor device having a MCFET and a finFET according to an embodiment of the present invention will be described with reference to FIGS. 1 to 12.

Referring to FIG. 1, a first hard mask pattern 541 and a second hard mask pattern 542 are formed on predetermined regions of a substrate 51. The first hard mask pattern 541 may have a width that is greater than that of the second hard mask pattern 542.

The substrate 51 may be a semiconductor substrate such as a silicon wafer or an SOI wafer. The substrate 51 may have a first region 10 and a second region 20. The first region 10 may be a peripheral circuit region of the semiconductor device, and the second region 20 may be a cell region. Alternatively, the first region 10 may be a pull-down transistor region of an SRAM cell, and the second region 20 may be a pass transistor region of the SRAM cell. The first hard mask pattern 541 may be formed on the first region 10, and the second hard mask pattern 542 may be formed on the second region 20.

Forming the first and second hard mask patterns 541 and 542 may include forming a hard mask layer on the substrate 51 and then patterning the hard mask layer using photolithography and etching processes. The first and second hard mask patterns 541 and 542 are preferably formed of a material layer having an etch selectivity with respect to the substrate 51. For example, the first and second hard mask patterns 541 and 542 may be formed of a nitride layer such as a silicon nitride layer.

Before the hard mask layer is formed, a pad layer may be formed on the substrate 51. The pad layer may be formed of a thermal oxide layer. The pad layer may act to relieve a stress applied between the hard mask layer and the substrate 51. In this case, the pad layer may be patterned together with the patterning of the hard mask layer so that a first pad pattern 531 and a second pad pattern 532 may be formed. The first pad pattern 531 may be aligned under the first hard mask pattern 541, and the second pad pattern 532 may be aligned under the second hard mask pattern 542. Alternatively, the first and second pad patterns 531 and 532 may be omitted.

The substrate 51 is etched using the first and second hard mask patterns 541 and 542 as etch masks to form trenches, which define a preliminary multi-fin 551 and a single fin 552. Etching the substrate 51 may be performed by an anisotropic etching process. The preliminary multi-fin 551 has first and second sidewalls 11 and 12 facing each other and a top surface 13. The single fin 552 also has first and second sidewalls 21 and 22 and a top surface 23. The preliminary multi-fin 551 may be aligned under the first hard mask pattern 541, and the single fin 552 may be aligned under the second hard mask pattern 542. Accordingly, the preliminary multi-fin 551 may have a width that is larger than that of the single fin 552. That is, the top surface 13 of the preliminary multi-fin 551 may have a width larger than the top surface 23 of the single fin 552.

As a result, the fins 551 and 552 protrude from the substrate 51 in a vertical direction. The preliminary multi-fin 551 and the single fin 552 may have substantially the same height. That is, the first and second sidewalls 11 and 12 of the preliminary multi-fin 551 and the first and second sidewalls 21 and 22 of the single fin 552 may have substantially the same height.

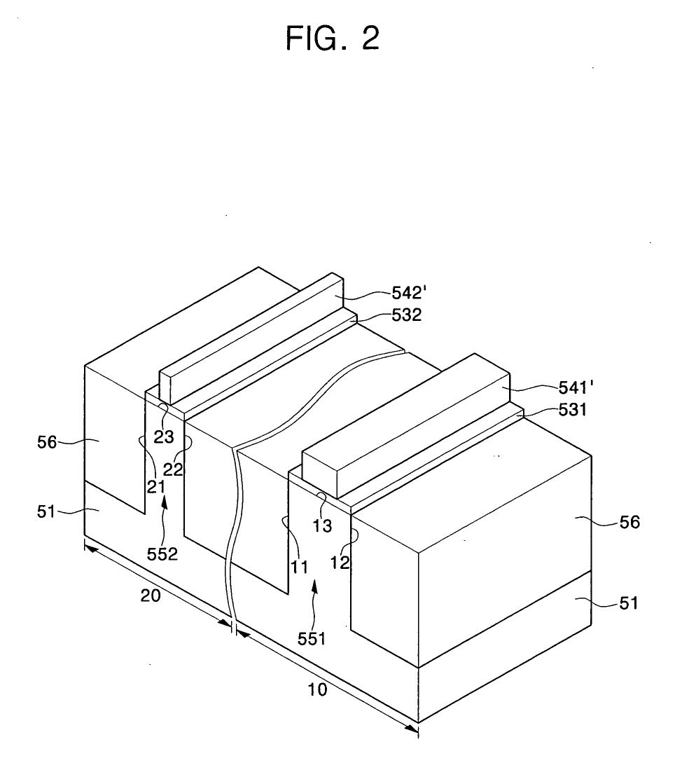

Referring to FIG. 2, an isolation layer 56 is formed to fill the trench. The isolation layer 56 may be formed of an insulating layer such as a silicon oxide layer. For example, an insulating layer filling the trench and covering the substrate 51 is formed and then etched-back until the top surface and sidewalls of the first and second hard mask patterns 541 and 542 are exposed, so that the isolation layer 56 may be formed. The top surface of the isolation layer 56 may have substantially the same level as the top surface 13 of the preliminary multi-fin 551 and the top surface 23 of the single fin 552.

A pull-back process is employed to form first and second hard mask reduced patterns 541′ and 542′. The pull-back process may include isotropically etching the first and second hard mask patterns 541 and 542. For example, the pull-back process may be performed until a width of the second hard mask reduced pattern 542′ is 10 nm or less. While the pull-back process is performed, the first and second hard mask patterns 541 and 542 may be etched at a uniform rate in proportion to their exposed areas.

Accordingly, the first hard mask reduced pattern 541′ may have a width that is greater than that of the second hard mask reduced pattern 542′. Alternatively, the second hard mask pattern 542 may be completely removed. That is, the pull-back process may be performed until the second hard mask pattern 542 is completely removed.

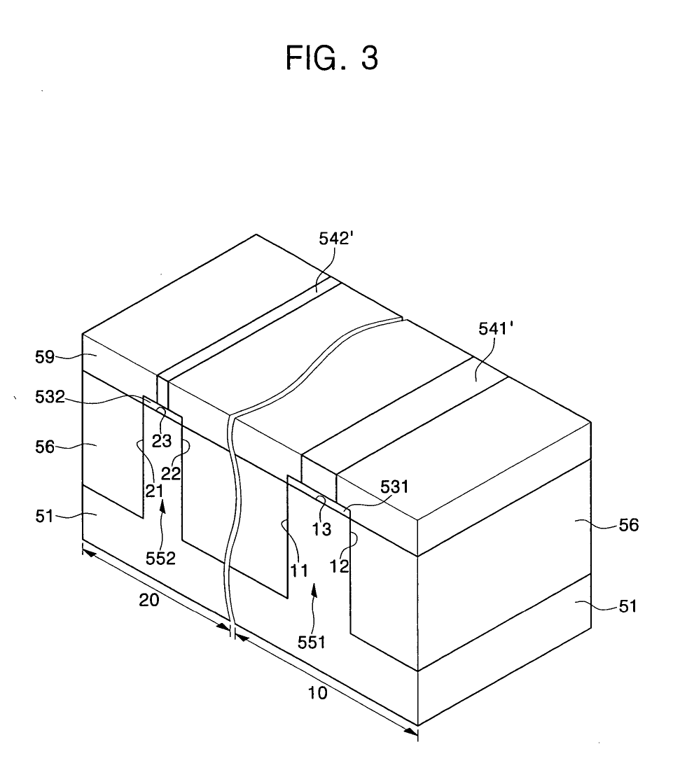

Referring to FIG. 3, a sacrificial layer 59 is formed on the substrate 51 having the first and second hard mask reduced patterns 541′ and 542′. The sacrificial layer 59 may expose top surfaces of the first and second hard mask reduced patterns 541′ and 542′.

Specifically, a material layer having an etch selectivity with respect to the first and second hard mask reduced patterns 541′ and 542′ may be formed on the substrate 51 and then planarized, so that the sacrificial layer 59 is formed. When the first and second hard mask reduced patterns 541′ and 542′ are the nitride layers, the sacrificial layer 59 may be formed of a silicon oxide layer. Planarizing the material layer may be performed by a chemical mechanical polishing (CMP) or an etch back process.

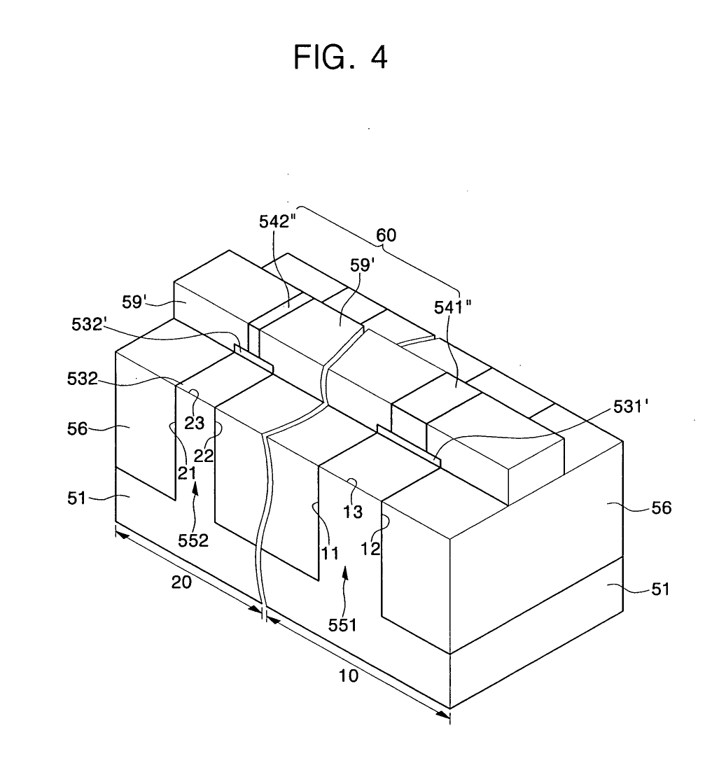

Referring to FIG. 4, the sacrificial layer 59 and the first and second hard mask reduced patterns 541′ and 542′ are patterned to form a sacrificial line 60 crossing the fins 551 and 552. The patterning may include forming a photoresist pattern on the sacrificial layer 59 and the first and second hard mask reduced patterns 541′ and 542′, and anisotropically etching the sacrificial layer 59 and the first and second hard mask reduced patterns 541′ and 542′ using the photoresist pattern as an etch mask. In this case, the anisotropic etching may be performed until the top surfaces 13 and 23 of the fins 551 and 552 at both sides of the sacrificial line 60 are exposed.

As a result, the sacrificial layer 59 and the first and second hard mask reduced patterns 541′ and 542′ may be patterned to form a sacrificial pattern 59′, and first and second sacrificial masks 541″ and 542″. The sacrificial pattern 59′, and the first and second sacrificial masks 541″ and 542″ may constitute the sacrificial line 60. That is, the first sacrificial mask 541″ may remain on the preliminary multi-fin 551 to divide the sacrificial pattern 59′. Similarly, the second sacrificial mask 542″ may remain on the single fin 552 to divide the sacrificial pattern 59′.

While the sacrificial line 60 is formed, the first and second pad patterns 531 and 532, when present, may also be patterned to form first and second sacrificial pad patterns 531′ and 532′. The first sacrificial pad pattern 531′ may remain between the preliminary multi-fin 551 and the first sacrificial mask 541″. The second sacrificial pad pattern 532′ may remain between the single fin 552 and the second sacrificial mask 542″.

Referring to FIG. 5, a passivation layer 61 is formed to cover the exposed top surfaces 13 and 23 of the fins 551 and 552. The passivation layer 61 is preferably formed of a material layer having an etch selectivity with respect to the first and second sacrificial masks 541″ and 542″. When the first and second sacrificial masks 541″ and 542″ are formed of a nitride layer, the passivation layer 61 may be formed of a silicon oxide layer.

Forming the passivation layer 61 may include forming a silicon oxide layer on the entire surface of the substrate 51 having the sacrificial line 60, and planarizing the silicon oxide layer until the top surfaces of the first and second sacrificial masks 541″ and 542″ are exposed. In this case, the top surfaces of the passivation layer 61, the sacrificial pattern 59′ and the first and second sacrificial masks 541″ and 542″ may be exposed on substantially the same plane.

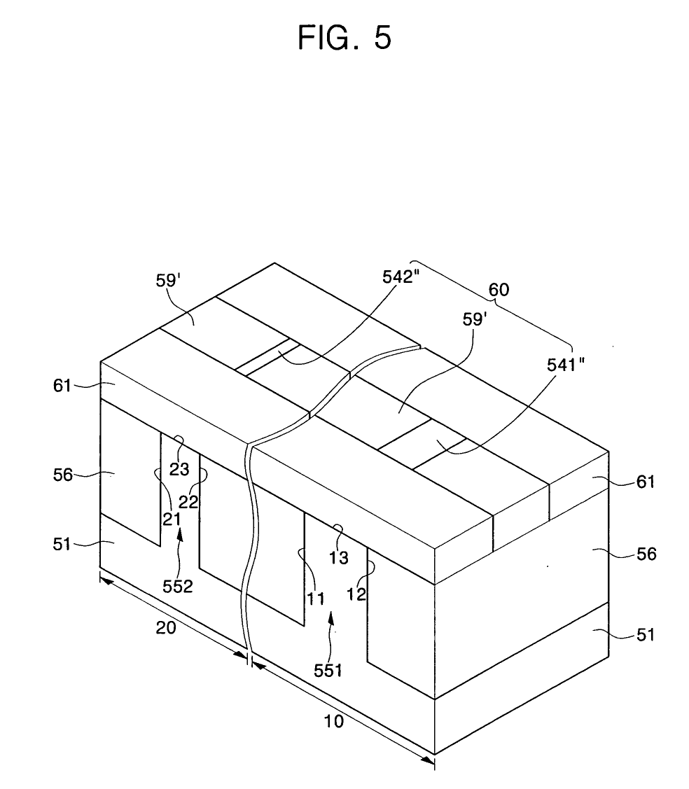

Referring to FIG. 6, the first and second sacrificial masks 541″ and 542″ are selectively removed to form first and second openings 541H and 542H.

The first and second sacrificial masks 541″ and 542″ have etch selectivities with respect to the sacrificial pattern 59′ and the passivation layer 61. Accordingly, the first and second openings 541H and 542H may be formed by an isotropic etching process capable of selectively removing the first and second sacrificial masks 541″ and 542″.

As a result, the top surface 13 of the preliminary multi-fin 551 may be exposed on a bottom surface of the first opening 541H. When the first sacrificial pad pattern 531′ is formed, the first sacrificial pad pattern 531′ may be exposed on the bottom surface of the first opening 541H. Similarly, the top surface 23 of the single fin 552 may be exposed on a bottom surface of the second opening 542H. When the second sacrificial pad pattern 532′ is formed, the second sacrificial pad pattern 532′ may be exposed on the bottom surface of the second opening 542H.

Subsequently, a spacer layer may be formed to fill the second opening 542H and to cover an inner wall of the first opening 541H. The spacer layer may be formed of a material layer having an etch selectivity with respect to the preliminary multi-fin 551. For example, the spacer layer may be formed of a silicon oxide layer. The spacer layer may be anisotropically etched to form a sacrificial plug 542P and a spacer 541S. The anisotropic etching may be performed until the top surface 13 of the preliminary multi-fin 551 is exposed on the bottom surface of the first opening 541H.

The first sacrificial pad pattern 531′, when present, may also be etched together while the spacer 541S is formed. The sacrificial plug 542P may completely fill the second opening 542H. The top surfaces of the passivation layer 61, the sacrificial pattern 59′, the sacrificial plug 542P and the spacer 541S may be exposed on substantially the same plane.

Alternatively, when the second hard mask pattern 542 is completely removed while the first hard mask reduced pattern 541′ is formed, the sacrificial plug 542P may be omitted. In this case, the single fin 552 may be covered by the passivation layer 61 and the sacrificial pattern 59′.

In this case, the passivation layer 61, the sacrificial pattern 59′, the sacrificial plug 542P, and the spacer 541S may constitute a multi-channel mask 66. As described above, the multi-channel mask 66 may have the first opening 541H which partially exposes the top surface 13 of the preliminary multi-fin 551. The first opening 541H may be aligned with the center region of the preliminary multi-fin 551.

Referring to FIGS. 7 and 8, a concave portion 641 is formed in the preliminary multi-fin 551 to form a multi-fin 551′.

The concave portion 641 may be formed by anisotropically etching the preliminary multi-fin 551 using the multi-channel mask 66 as an etch mask. The concave portion 641 may be formed below the first opening 541H. Accordingly, the concave portion 641 may be aligned in the center of the multi-fin 551′. In addition, the multi-fin 551′ may be divided into first and second fins F1 and F2 by the concave portion 641.

As described above, the second opening 542H is completely filled by the sacrificial plug 542R Accordingly, the single fin 552 may be protected during the anisotropic etching. That is, the concave portion 641 may be selectively formed in the multi-fin 551′.

Referring to FIGS. 9 and 10, the multi-fin 551′ and the single fin 552 are exposed. in detail, the multi-channel mask 66 may be removed by an isotropic etching process. For example, the isotropic etching process may be performed using an oxide etchant containing hydrofluoric acid. While the isotropic etching process is performed, the first sacrificial pad pattern 531′ and the second sacrificial pad pattern 532′ may also be removed at the same time. The isotropic etching process may optionally be separately performed using different etching conditions from each other at least twice. Subsequently, the isolation layer 56 is etched to be recessed. Etching of the isolation layer 56 may also be performed using the isotropic etching process.

As a result, a recessed portion of the isolation layer 56′ may remain below the top surfaces 13 and 23 of the fins 551′ and 552. That is, the sidewalls 11, 12, 21, and 22 and the top surfaces 13 and 23 of the fins 551′ and 552 may be exposed. In addition, a third sidewall 15, a fourth sidewall 16, and a bottom surface 17 of the multi-fin 551′ may be exposed in the concave portion 641. In this case, the first fin F1 may include the first sidewall 11, the third sidewall 15, and the top surface 13, and the second fin F2 may include the second sidewall 12, the fourth sidewall 16, and the top surface 13.

Referring to FIGS. 11 and 12, a gate dielectric layer 71 is formed on the multi-fin 551′ and the single fin 552. The gate dielectric layer 71 may be formed of a silicon oxide layer, a silicon nitride layer, a silicon oxynitride layer, a high-k dielectric layer, or a combination layer thereof. The gate dielectric layer 71 may also be formed on the inner wall of the concave portion 641.

A gate conductive layer is formed on the substrate 51 having the gate dielectric layer 71. The gate conductive layer may be formed of a polysilicon or metal layer. The gate conductive layer is patterned to form a first gate electrode 731 crossing the multi-fin 551′ and a second gate electrode 732 crossing the single fin 552.

The first gate electrode 731 may cover the sidewalls 11 and 12 and the top surface 13 of the multi-fin 551′. While the gate conductive layer is formed, the concave portion 641 (see FIGS. 8 and 10) may also be filled with the gate conductive layer. Accordingly, the first gate electrode 731 may have a gate extension 731E that extends into the concave portion 641. The gate extension 731E may completely fill the concave portion 641. In this case, the third sidewall 15 and the fourth sidewall 16 of the multi-fin 551′ operate to extend the effective channel width of the resulting transistor.

The second gate electrode 732 may cover the sidewalls 21 and 22 and the top surface 23 of the single fin 552. Alternatively, the second gate electrode 732 may be formed to cover only a sidewall of the single fin 552.

Subsequently, a typical semiconductor fabrication process including the formation of source and drain regions within the multi-fin 551′ and the single fin 552 may be employed to complete the semiconductor device.

The multi-fin 551′, the gate dielectric layer 71, and the first gate electrode 731 may constitute a MCFET. In addition, the single fin 552, the gate dielectric layer 71, and the second gate electrode 732 may constitute a finFET.

Hereinafter, a semiconductor device having a MCFET and a finFET according to an embodiment of the present invention will be described with reference to FIGS. 11 and 12.

Referring to FIGS. 11 and 12, a multi-fin 551′ structure and a single fin 552 structure are disposed on a substrate 51.

The substrate 51 may be a semiconductor substrate such as a silicon wafer or an SOI wafer. The substrate 51 may have a first region 10 and a second region 20. The first region 10 may be a peripheral circuit region of the semiconductor device, and the second region 20 may be a cell region. In addition, the first region 10 may be a pull-down transistor region of an SRAM cell, and the second region 20 may be a pass transistor region of the SRAM cell. The multi-fin 551′ may be disposed in the first region 10, and the single fin 552 may be disposed in the second region 20.

The multi-fin 551′ protrudes from the substrate 51 in a vertical direction and includes a concave portion 641. (see FIGS. 8 and 10) The concave portion 641 may be aligned in the center of the multi-fin 551′. The multi-fin 551′ has first and second sidewalls 11 and 12 facing each other and a top surface 13. In addition, the multi-fin 551′ has a third sidewall 15, a fourth sidewall 16, and a bottom surface 17 within the concave portion 641.

The single fin 552 protrudes from the substrate 51 in a vertical direction and has a width that is smaller than that of the multi-fin 551′. The single fin 552 also has first and second sidewalls 21 and 22 and a top surface 23.

The first and second sidewalls 11 and 12 of the multi-fin 551′ and the first and second sidewalls 21 and 22 of the single fin 552 may have substantially the same height. That is, the multi-fin 551′ and the single fin 552 have substantially the same height.

A recessed isolation layer 56′ may be disposed on the substrate 51 near the multi-fin 551′ and the single fin 552. A top surface of the recessed isolation layer 56′ may be disposed below the top surfaces 13 and 23 of the fins 551′ and 552. The recessed isolation layer 56′ may be an insulating layer such as a silicon oxide layer.

A first gate electrode 731 and a second gate electrode 732 are disposed on the substrate 51 having the recessed isolation layer 56′. The gate electrodes 731 and 732 may be formed of a polysilicon or metal layer. A gate dielectric layer 71 is interposed between the fins 551′ and 552 and the gate electrodes 731 and 732. The gate dielectric layer 71 may be a silicon oxide layer, a silicon nitride layer, a silicon oxynitride layer, a high-k dielectric layer, or a combination layer thereof.

The first gate electrode 731 is disposed to cross the multi-fin 551′. The first gate electrode 731 may have a gate extension 731E inserted into the concave portion 641. The gate extension 731E may completely fill the concave portion 641. In addition, the first gate electrode 731 may be disposed to cover the first and second sidewalls 11 and 12 of the multi-fin 551′.

The second gate electrode 732 is disposed to cross the single fin 552. In addition, the second electrode 732 may be disposed to cover the first and second sidewalls 21 and 22 of the single fin 552.

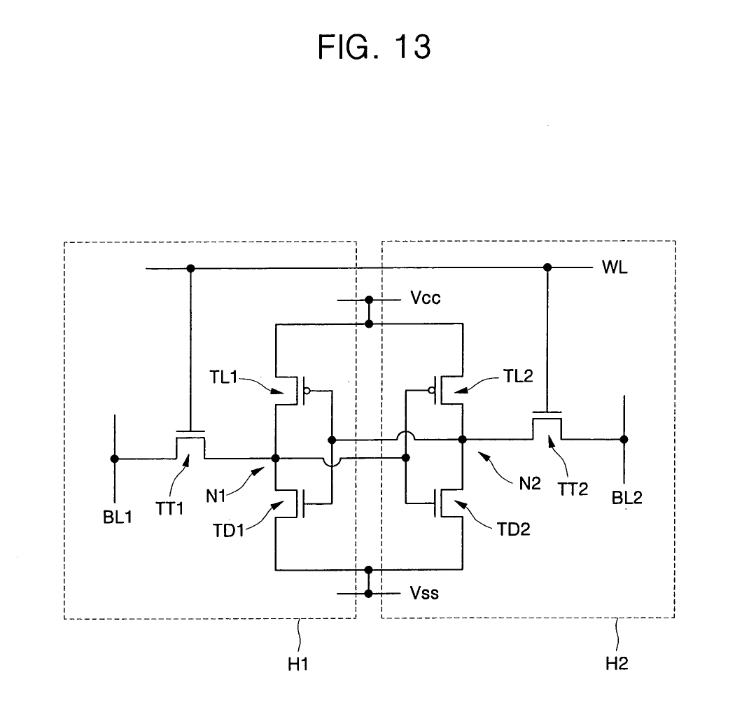

FIG. 13 is an equivalent circuit diagram of a CMOS SRAM cell having a MCFET and a finFET in accordance with an embodiment of the present invention.

Referring to FIG. 13, the CMOS SRAM cell has a pair of driver transistors TD1 and TD2, a pair of transfer transistors TT1 and TT2, and a pair of load transistors TL1 and TL2. The driver transistors TD1 and TD2 may be referred to as pull-down transistors, the transfer transistors TT1 and TT2 may be referred to as pass transistors, and the load transistors TL1 and TL2 may be referred to as pull-up transistors. The driver transistors TD1 and TD2 and the transfer transistors TT1 and TT2 are NMOS transistors whereas the load transistors TL1 and TL2 are PMOS transistors.

The first driver transistor TD1 and the first transfer transistor TT1 are connected in series to each other. A source region of the first driver transistor TD1 is electrically connected to a ground line Vss, and a drain region of the first transfer transistor TT1 is electrically connected to a first bit line BL1. Similarly, the second driver transistor TD2 and the second transfer transistor TT2 are connected in series to each other. A source region of the second driver transistor TD2 is electrically connected to the ground line Vss, and a drain region of the second transfer transistor TT2 is electrically connected to a second bit line BL2.

Source and drain regions of the first load transistor TL1 are electrically connected to a power supply line Vcc and a drain region of the first driver transistor TD1, respectively. Similarly, source and drain regions of the second load transistor TL2 are electrically connected to the power supply line Vcc and a drain region of the second driver transistor TD2, respectively. The drain region of the first load transistor TL1, the drain region of the first driver transistor TD1, and the source region of the first transfer transistor TT1 correspond to a first node N1. In addition, the drain region of the second load transistor TL2, the drain region of the second driver transistor TD2, and the source region of the second transfer transistor TT2 correspond to a second node N2. A gate electrode of the first driver transistor TD1 and a gate electrode of the first load transistor TL1 are electrically connected to the second node N2, and a gate electrode of the second driver transistor TD2 and a gate electrode of the second load transistor TL2 are electrically connected to the first node N1. In addition, gate electrodes of the first and second transfer transistors TT1 and TT2 are electrically connected to a word line WL.

The first driver transistor TD1, the first transfer transistor TT1, and the first load transistor TL1 constitute a first half cell H1, and the second driver transistor TD2, the second transfer transistor TT2, and the second load transistor TL2 constitute a second half cell H2.

An on current flowing through the transfer transistors TT1 and TT2 may be denoted as Ips, and an on current flowing through the driver transistors TD1 and TD2 may be denoted as Ipd. In addition, a value of Ipd/Ips may be denoted as a cell ratio. The CMOS SRAM cell has excellent electrical characteristics when the cell ratio is 1 or more. For example, the CMOS SRAM cell requires a cell ratio of 1.2 or more.

Referring to FIGS. 11 to 13, the multi-fin 551′, the gate dielectric layer 71, and the first gate electrode 731 may constitute a MCFET. In addition, the single fin 552, the gate dielectric layer 71, and the second gate electrode 732 may constitute a finFET. The third and fourth sidewalls 15 and 16 of the multi-fin 551′ may operate to extend the effective channel width of the corresponding transistor.

In general, the on current of the FET increases in proportion to the effective channel width. The MCFET may be disposed to operate as the driver transistors TD1 and TD2. The finFET may be disposed to operate as the transfer transistors TT1 and TT2. In this case, the cell ratio may become 1 or more. According to the present invention, the MCFET and the finFET may be formed on a single, common, substrate. In this manner, a CMOS SRAM cell having excellent electrical characteristics can be implemented.

According to the present invention as described above, a multi-fin and a single fin may be simultaneously formed on a single, common, substrate. Accordingly, a MCFET and a finFET may be formed together. That is, FETs having different on-currents relative to each other may be simultaneously formed. Consequently, mass production efficiency of the semiconductor device having an excellent electrical characteristics is improved.

While this invention has been particularly shown and described with references to preferred embodiments thereof, it will be understood by those skilled in the art that various changes in form and details may be made herein without departing from the spirit and scope of the invention as defined by the appended claims. For example, the present invention may be applied to a DRAM, an SRAM, other semiconductor devices, and methods of fabricating the same.

What is claimed is:

1. A method of fabricating a semiconductor device, comprising:
forming a first hard mask pattern and a second hard mask pattern on a substrate, the second hard mask pattern having a width in a horizontal direction that is less than that of the first hard mask pattern, and the second hard mask pattern being spaced apart from the first hard mask pattern;
partially removing the substrate using the first and second hard mask patterns as etch masks, and forming a preliminary multi-fin structure below the first hard mask pattern and a single fin structure below the second hard mask pattern; and
forming a concave portion in the preliminary multi-fin structure to form a multi-fin structure.

2. The method according to claim 1, wherein the first and second hard mask patterns are formed of a nitride layer.

3. The method according to claim 1, wherein the concave portion is positioned in a central region of the multi-fin structure in the horizontal direction.

4. The method according to claim 1, wherein forming the concave portion comprises:
forming a multi-channel mask on the substrate, the multi-channel mask having a first opening partially exposing a top surface of the preliminary multi-fin structure; and
anisotropically etching the preliminary multi-fin structure using the multi-channel mask as an etch mask.

5. The method according to claim 4, wherein forming the multi-channel mask comprises:
etching the first and second hard mask patterns using a pull-back process to form a first hard mask reduced pattern on the preliminary multi-fin structure;
forming a sacrificial layer covering the substrate and exposing a top surface of the first hard mask reduced pattern;
patterning the sacrificial layer and the first hard mask reduced pattern to form a sacrificial line that crosses over the preliminary multi-fin structure and the single fin structure in the horizontal direction, the sacrificial line having a sacrificial pattern and a first sacrificial mask;
forming a passivation layer on the substrate at both sides of the sacrificial line; and
selectively removing the first sacrificial mask.

6. The method according to claim 5, wherein the pull-back process is performed until the second hard mask pattern is completely removed.

7. The method according to claim 4, wherein forming the multi-channel mask comprises:
partially removing the first and second hard mask patterns using a pull-back process to form a first hard mask reduced pattern and a second hard mask reduced pattern;
forming a sacrificial layer covering the substrate and exposing top surfaces of the first and second hard mask reduced patterns;
patterning the sacrificial layer and the first and second hard mask reduced patterns to form a sacrificial line that crosses over the preliminary multi-fin structure and the single fin structure, the sacrificial line having a sacrificial pattern, a first sacrificial mask, and a second sacrificial mask;
forming a passivation layer on the substrate at both sides of the sacrificial line;
selectively removing the first and second sacrificial masks to form the first opening and a second opening; and
forming a spacer on inner sidewalls of the first opening, and forming a sacrificial plug in the second opening.

8. The method according to claim 7, wherein the pull-back process comprises isotropically etching the first and second hard mask patterns.

9. The method according to claim 7, wherein the sacrificial layer and the passivation layer are formed of a material layer having an etch selectivity with respect to the hard mask patterns.

10. The method according to claim 7, wherein forming the spacer and the sacrificial plug comprises:
forming a spacer layer filling the second opening and covering an inner wall of the first opening; and
anisotropically etching the spacer layer until the top surface of the preliminary multi-fin structure is exposed on a bottom surface of the first opening.

11. The method according to claim 1, wherein the multi-fin structure and the single fin structure have substantially the same height.

12. A method of fabricating a static random access memory (SRAM) cell, comprising:
forming a preliminary multi-fin structure and a single fin structure on a substrate that extend from the substrate in a vertical direction, the preliminary multi-fin structure having a width in a horizontal direction that is greater than that of the single fin structure;
forming a concave portion in the preliminary multi-fin structure to form a multi-fin structure;
forming a gate dielectric layer on the multi-fin structure and the single fin structure; and
forming a first electrode crossing the multi-fin structure and a second gate electrode crossing the single fin structure.

13. The method according to claim 12, wherein forming the preliminary multi-fin structure and a single fin structure comprises:
forming a first hard mask pattern and a second hard mask pattern on the substrate, the second hard mask pattern having a width in the horizontal direction that is less than that of the first hard mask pattern, the first and second hard mask patterns being spaced apart from each other; and
partially removing the substrate using the hard mask patterns as etch masks,
wherein the preliminary multi-fin structure is formed under the first hard mask pattern and the single fin structure is formed under the second hard mask pattern.

14. The method according to claim 13, wherein the first and second hard mask patterns are formed of a nitride layer.

15. The method according to claim 13, wherein forming the concave portion comprises:
forming a multi-channel mask on the substrate, the multi-channel mask having a first opening partially exposing a top surface of the preliminary multi-fin structure; and
anisotropically etching the preliminary multi-fin structure using the multi-channel mask as an etch mask.

16. The method according to claim 15, wherein forming the multi-channel mask comprises:
partially removing the first and second hard mask patterns using a pull-back process to form a first hard mask reduced pattern and a second hard mask reduced pattern;
forming a sacrificial layer covering the substrate and exposing top surfaces of the first and second hard mask reduced patterns;
patterning the sacrificial layer and the hard mask reduced patterns to form a sacrificial line that crosses over the preliminary multi-fin structure and the single fin structure, the sacrificial line having a sacrificial pattern, a first sacrificial mask, and a second sacrificial mask;
forming a passivation layer on the substrate at both sides of the sacrificial line;
selectively removing the first and second sacrificial masks to form the first opening and a second opening; and
forming a spacer on inner sidewalls of the first opening, and forming a sacrificial plug in the second opening.

17. The method according to claim 16, wherein the sacrificial layer and the passivation layer are formed of a material layer having an etch selectivity with respect to the first and second hard mask patterns.

18. The method according to claim 12, wherein the first gate electrode fills the concave portion and covers at least one sidewall of the multi-fin structure, and the second gate electrode covers at least one sidewall of the single fin structure.

19. A semiconductor device comprising:
a substrate;
a multi-fin structure that extends from the substrate in a vertical direction, the multi-fin structure including a concave portion in a top portion thereof;
a single fin structure that protrudes from the substrate in the vertical direction, the single-fin structure spaced apart from the multi-fin structure and having a width that is less than that of the multi-fin structure;
a first gate electrode crossing the multi-fin structure;
a second gate electrode crossing the single fin structure and covering at least one sidewall of the single fin structure; and
a gate dielectric layer interposed between the multi-fin structure and the single fin structure and between the first and second gate electrodes.

20. The semiconductor device according to claim 19, wherein the concave portion is positioned in a central region of the multi-fin structure in the horizontal direction, and the first gate electrode fills the concave portion and covers at least one sidewall of the multi-fin structure.

21. The semiconductor device according to claim 19, wherein the multi-fin structure and the single fin structure have substantially the same height.

22. The semiconductor device according to claim 19, wherein the second gate electrode covers both sidewalls of the single fin structure.
